(19) United States
(12) Patent Application Publication
(10) Pub. No.: US 2013/0271193 A1
(43) Pub. Date: Oct. 17, 2013

(54) CIRCUITS AND METHODS TO GUARANTEE LOCK IN DELAY LOCKED LOOPS AND AVOID HARMONIC LOCKING

(71) Applicant: Colby Keith, Santa Clara, CA (US)

(72) Inventor: Colby Keith, Santa Clara, CA (US)

(73) Assignee: INTERSIL AMERICAS LLC, Milpitas, CA (US)

(21) Appl. No.: 13/532,241

(22) Filed: Jun. 25, 2012

Related U.S. Application Data
(60) Provisional application No. 61/624,159, filed on Apr. 13, 2012.

(51) Int. Cl. H03L 7/08

(52) U.S. Cl. 327/158

(57) ABSTRACT

A delay locked loop (DLL) includes a phase detector (PD), a lock assistor (LA), a control voltage generator, and a voltage controlled delay line (VCDL). The PD determines a phase difference between of a reference clock and a delayed version of the reference clock and produces a pair of phase detector output signals in dependence on the determined phase difference. The LA receives the pair of phase detector output signals and produces a pair of lock assist output signals by selectively swapping the phase detector output signals. The control voltage generator receives the pair of lock assist output signals and produces a control voltage signal in dependence on thereon. The VCDL receives the control voltage signal and the reference clock (or a buffered version thereof) and outputs the delayed version of the reference clock, with a delay through the VCDL being dependent on the received control voltage signal.

### PRIORITY CLAIM

This application claims priority under 35 U.S.C. 119(e) to U.S. Provisional Patent Application No. 61/624,159, filed Apr. 13, 2012, which is incorporated herein by reference.

### BACKGROUND

A delay locked loop (DLL) is preferably locked such that the relationship of a clock edge of the output clock from the DLL to a clock edge from a reference clock edge is exactly 360 degrees away (i.e., delayed by exactly 2π radians). However, depending upon the design of the phase detector (PD) of the DLL and the total amount of phase delay through the voltage controlled delay line (VCDL), it is possible that the DLL may never lock. It is also a common problem for a DLL to lock such that the relationship of a clock edge of the output clock from the DLL to a clock edge from a reference clock edge is not exactly 360 degrees away (i.e., not delayed by exactly 2π radians). For an example, if the total available phase delay through the VCDL of the DLL is greater than 3π radians, with a minimum phase delay of π radians, then there are multiple edges of the reference clock to which the DLL can potentially lock, such that, for example, the phase relationship between the input reference clock and output DLL clock is 4π radians, 6πradians etc. If the edges further in delay are locked to, jitter can increase, degrading DLL performance. This problem is known as harmonic locking.

### BRIEF DESCRIPTION OF THE FIGURES

FIG. 1 is a diagram of an exemplary analog delay locked loop (DLL).

FIG. 2A is a timing diagram showing ideal UP and DN signals when the phase difference between the delayed DLL clock and the reference clock equals 2π radians.

FIG. 2B illustrates a dead zone in the transfer function of the phase detector and the charge pump of the DLL of FIG. 1.

FIG. 3 illustrates a Laplace domain model of the DLL of FIG. 1.

FIG. 4A is a timing diagram that illustrates phase detector behavior in the case where the phase delay<π radians through the VCDL.

FIG. 4B is a timing diagram that illustrates phase detector behavior in the case where the phase delay>π radians, and <2π radians through the VCDL.

FIG. 4C is a timing diagram that illustrates phase detector behavior in the case where the phase delay is >2π radians, and <3π radians through the VCDL.

FIG. 4D is a timing diagram that illustrates phase detector behavior in the case where the phase delay>3π radians through the VCDL.

FIG. 5 is a diagram of a DLL according to an embodiment of the present invention.

FIG. 6A is a diagram of the lock assistor (LA) shown in FIG. 5, according to an embodiment of the present invention.

FIG. 6B is a timing diagram that illustrates operation of the lock assistor (LA) of FIG. 6A.

FIG. 7 shows the relationship between the voltage on the loop filter (LF) of the DLL in FIG. 5 relative to the multiplexer control signal labeled “swap”.

FIG. 8 is a diagram of a DLL according to another embodiment of the present invention.

FIG. 9 is a high level flow diagram that is used to summarize methods according to various embodiments of the present invention.

FIG. 10 illustrates an eye monitor circuit including a DLL, according to an embodiment of the present invention.

FIG. 11 is used to illustrate how a DLL of an embodiment of the present invention can be used to synchronize signals, within a subsystem that is part of a larger system, to a clock of the larger system.

### DETAILED DESCRIPTION

In the following detailed description, reference is made to the accompanying drawings that form a part hereof, and in which is shown by way of illustration specific illustrative embodiments. It is to be understood that other embodiments may be utilized and that mechanical and electrical changes may be made. The following detailed description is, therefore, not to be taken in a limiting sense. In the description that follows, like numerals or reference designators will be used to refer to like parts or elements throughout. In addition, the first digit of a reference number identifies the drawing in which the reference number first appears.

As mentioned above, a DLL is preferably locked such that the relationship of a clock edge of the output clock from the DLL to a clock edge from an input reference clock edge is exactly 360 degrees away (i.e., delayed by exactly 2π radians). However, if the total phase delay range through the VCDL of the DLL is greater than 2π radians, such that the minimum phase delay through the VCDL is less than π radians, then depending upon the design of the PD of the DLL, it is possible that the DLL may never lock. This may occur when: 1) the phase detector has a symmetrical design such that the case of phase relationship of input reference clock to output reference clock of <π radians is treated the same as the case of phase relationship of input reference clock to output reference clock of >2π radians and <3π radians; and 2) the total phase delay range through a voltage controlled delay line (VCDL) of the DLL is greater than 2π radians, such that the minimum phase delay is less than π radians. Embodiments of the present invention, described below, address this problem. Another potential problem mentioned above is the problem of harmonic locking, which can occur if the total available phase delay through the VCDL of the DLL is greater than 3π radians, with a minimum phase delay of π radians, resulting in multiple edges of the reference clock to which the DLL can potentially lock. Embodiments of the present invention, described below, also address this problem.

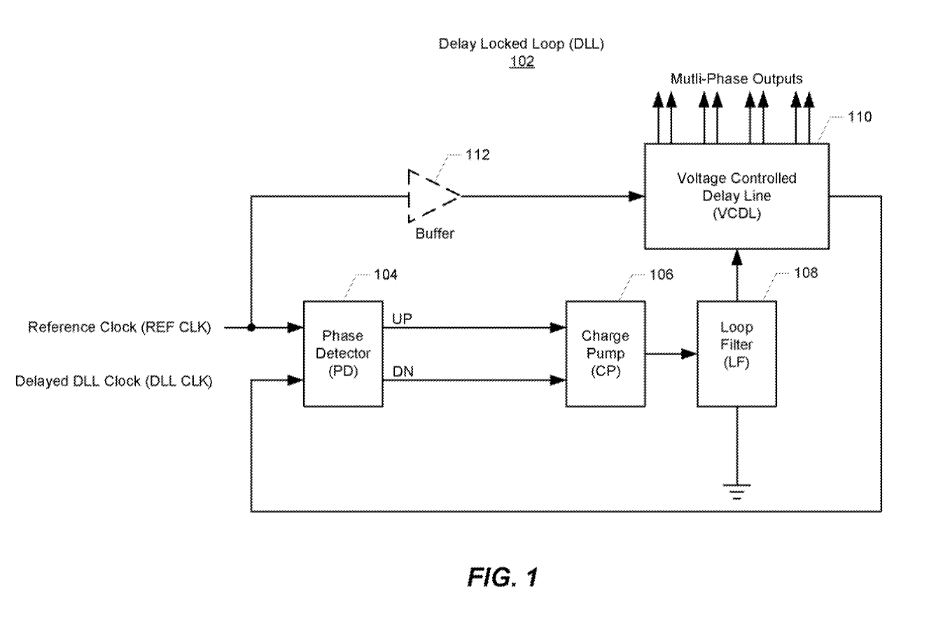

Before describing specific embodiments of the present invention, it is first useful to describe an exemplary analog DLL and its operation. FIG. 1 is a diagram of an exemplary analog DLL 102. The DLL 102 includes a phase detector (PD) 104, a charge pump (CP) 106, a loop filter (LF) 108 and a voltage controlled delay line (VCDL) 110. The PD 104 has a pair of inputs, one of which accepts a reference clock (REF CLK), and the other which accepts a delayed DLL clock signal (DLL CLK). The delayed DLL clock signal can also be referred to as a delayed version of the reference clock. The PD 104 also has a pair of outputs (labeled UP and DN) that output UP and DN signals, which can also be referred to as phase detector output signals, or simply as phase detection signals. A binary UP signal (provided at the UP output) and a binary DN signal (provided at the DN output) can each either have a low (e.g., 0) state or a high (e.g., 1) state. These phase detection signals (i.e., the UP and DN signals) are input to the CP 106. The CP 106 sources or sinks current depending upon whether the UP or DN output from the PD 104 is high. For example, the CP sources current when the UP output from the PD 104 is high, and the CP sinks current when the DN output from the PD is high. The LF 108 converts the current from the CP 106 into a control voltage signal which is input to the VCDL 110. The delay through the VCDL 110 is proportional to the control voltage signal output by the LF 108. An optional buffer 112 receives the reference clock and provides the reference clock (or more specifically, a buffered version thereof) to the VCDL 110. Where the buffer 112 is not included, or is implemented as part of the VCDL 110, the reference clock is provided directly to the VCDL 110. The VCDL 110 outputs a delayed DLL clock signal (DLL CLK), which is fed back to one of the inputs of the PD 104. The VCDL 110 also produces multi-phase outputs which can be used to, e.g., for clock data recovery, to drive a phase interpolator used to generate a single phase clock, to control multi-phase sampling of a serial data stream, and/or for various other applications. It is also noted that the VCDL 110 can alternatively produce a single-phase output.

The DLL 102 operates as follows. The phase of the reference clock signal (REF CLK) is compared to the phase of the delayed DLL clock (DLL CLK) which is output from the VCDL 110. If the phase of the delayed DLL clock is <2π radians relative to the reference clock (i.e., if the phase difference, ΔΦ, between the delayed DLL clock and the reference clock is <2π radians), then the UP output of the PD 104 is high (and the DN output of the PD 104 is low) for the duration of the phase difference. If the phase of the delayed DLL clock is >2π radians relative to the reference clock (i.e., if the phase difference, ΔΦ, between the delayed DLL clock and the reference clock is >2π radians), then the DN output of the PD 104 is high (and the UP output of the PD 104 is low) for the duration of the phase difference. While the UP signal is high, the CP 106 sources current, raising the voltage on the LF 108. Conversely, while the DN signal is high, the CP 106 sinks current, lowering the voltage on the LF 108.

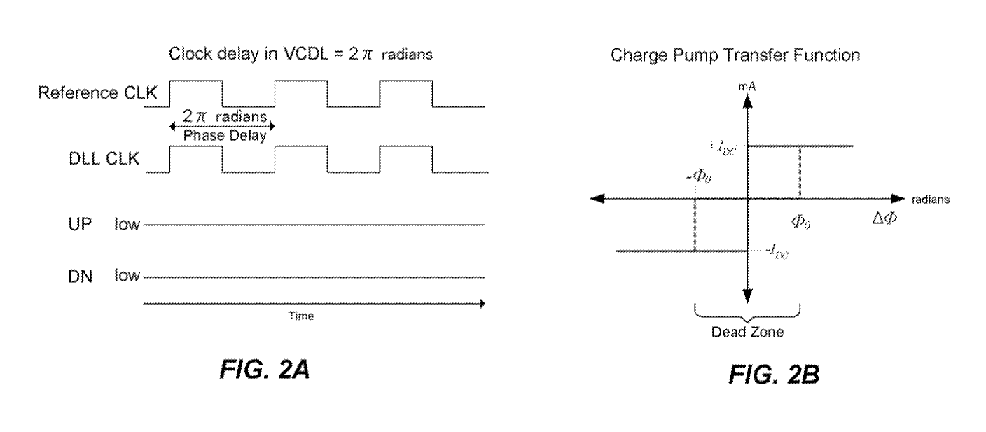

As the control voltage signal output by the LF 108 increases, the delay of the clock through the VCDL 110 increases until the phase of the reference clock and delayed DLL clock are equivalent, and more specifically, until the phase difference, ΔΦ, between the reference clock and the delayed DLL clock equals 2π radians. If there are perturbations on the voltage output of the LF 108 from noise, the feedback loop forces the voltage back to a point such that the phase difference between the reference clock and the delayed DLL clock are again equal to 2π radians. When the phase difference, ΔΦ, between reference clock and the delayed DLL clock is equal to 2π radians, then both the UP and DN signals should be low, as shown in FIG. 2A. However, it is noted that in actual implementations of DLLs, in order to prevent a dead zone in the transfer function of the PD 104 and the CP 106 (which can lead to poor locking and high jitter) the PD 104 is designed such that the UP and DN signals are both high for a short period of time when either of them is meant to be high based upon the phase relationship of the two clocks input to the PD 104. An exemplary dead zone is illustrated in FIG. 2B.

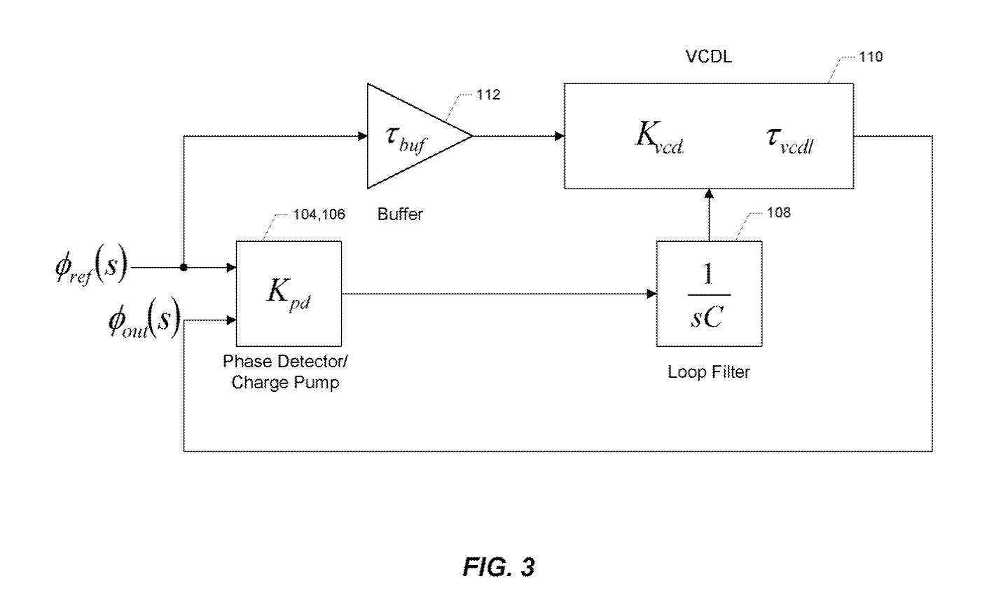

FIG. 3 shows a Laplace domain model constructed for the DLL 102, which can be used to derive the jitter transfer function from the input reference clock to the delayed DLL clock, and which is given by the following equation

$$\frac{{φ}_{out} ( s )}{{φ}_{ref} ( s )} = \frac{{ε}^{- ( {τ}_{buf} + {τ}_{vcdl} ) s} + {K}_{pd} {K}_{vedl} {H}_{f} ( s )}{1 + {K}_{pd} {K}_{vedl} {H}_{f} ( s )} \qquad ( 1 )$$

where φₒᵤₜ is the phase of the delayed DLL clock produced by the VCDL 110 of the DLL 102, φ_{ref} is the phase of the reference clock input to the DLL 102, τ_{buf} is the time delay through any buffer(s) (e.g., 112) carrying the clock signal prior to the VCDL 110, τ_{vedl} is the time delay through the VCDL 110, K_{pd} is the gain of the PD 104, K_{vedl} is the gain of the VCDL 110, and H_{f}(s) is the transfer function of the LF 108. Generally, K_{vedl} changes as the phase is increased through the VCDL 110, since the transfer function of the VCDL 110 is not linear. Also, K_{pd} is given by the following equation

$${K}_{pd} = \frac{{I}_{cp}}{2 π} \qquad ( 2 )$$

where I_{cp} is the DC current of the CP 106 (up or down). The loop transfer function is simply

$${H}_{f} ( s ) = \frac{1}{sC} . \qquad ( 3 )$$

If it is assumed that the LF 108 is a capacitor, yielding a single pole, than the transfer function can be rewritten as follows

$$\frac{{φ}_{out} ( s )}{{φ}_{ref} ( s )} = \frac{1 + ( s \text{/} {ω}_{p} ) \cdot {e}^{- ( {τ}_{buf} + {τ}_{vedl} ) s}}{1 + ( s \text{/} {ω}_{p} )} \qquad ( 4 )$$

such that the pole ωₚ is given by

$${ω}_{p} = \frac{{I}_{cp} {K}_{vedl}}{2 π C} .. \qquad ( 5 )$$

This model can be used in design for optimizing the jitter as well as for determining the values of the charge pump current and loop filter capacitor that will lead to proper lock. In the case of the DLL of a specific embodiment of the present invention, the jitter is optimized for a locked condition with the K_{vedl} that is seen at a phase delay of 2π radians.

For proper operation of the DLL 102 as described above, it is assumed that the range of phase delay through the VCDL should be >π radians and <3π radians. This gives a total phase delay range of 2π radians. This phase should be offset by π radians. In other words, the minimum delay through the VCDL 110 should be π radians and the maximum delay should be 3π radians. If the total phase delay range is greater than 2πradians, then there are several problems that can occur.

First, if the total phase delay range is >2π radians, such that the minimum phase delay<π radians, then depending upon the design of the PD 104, it is possible that the DLL 102 may never lock. An example of this problem is as follows. Assume that the PD 104 is designed such that the UP and DN outputs are reset on any edge input to the PD 104. When the minimum phase delay through the VCDL 110 is <π radians, which is a possibility given process voltage and temperature variations, the PD 104 will generate UP pulses, since the delayed DLL clock will appear to lead the reference clock (i.e., there will appear to be phase delay greater than 2π radians). This phase relationship between the reference clock (which can also be referred to as the input reference clock) and the delayed DLL clock (which can also be referred to as the DLL output clock, or the delayed version of the reference clock) is identical to the case in which the DLL output clock is delayed by an amount greater than 3π radians. If UP pulses are output from the PD 104 when the phase delay is actually <π radians, the DLL control loop will try to decrease the DLL phase delay. However, since the phase delay is already at a minimum, it cannot actually decrease the phase delay. Instead, the control voltage signal output by the LF 108 will correspond to a minimum voltage and will be pegged there, forcing the DLL 102 to always output a clock with a minimum delay, preventing the DLL from ever locking.

Second, if the total phase delay through the VCDL 110 is >3π radians with a minimum phase delay of π radians, then there are multiple edges of the reference clock to which the DLL 102 can potentially lock. As the edges further in delay are locked to, jitter can increase, degrading DLL performance. This problem is known as harmonic locking, as mentioned above.

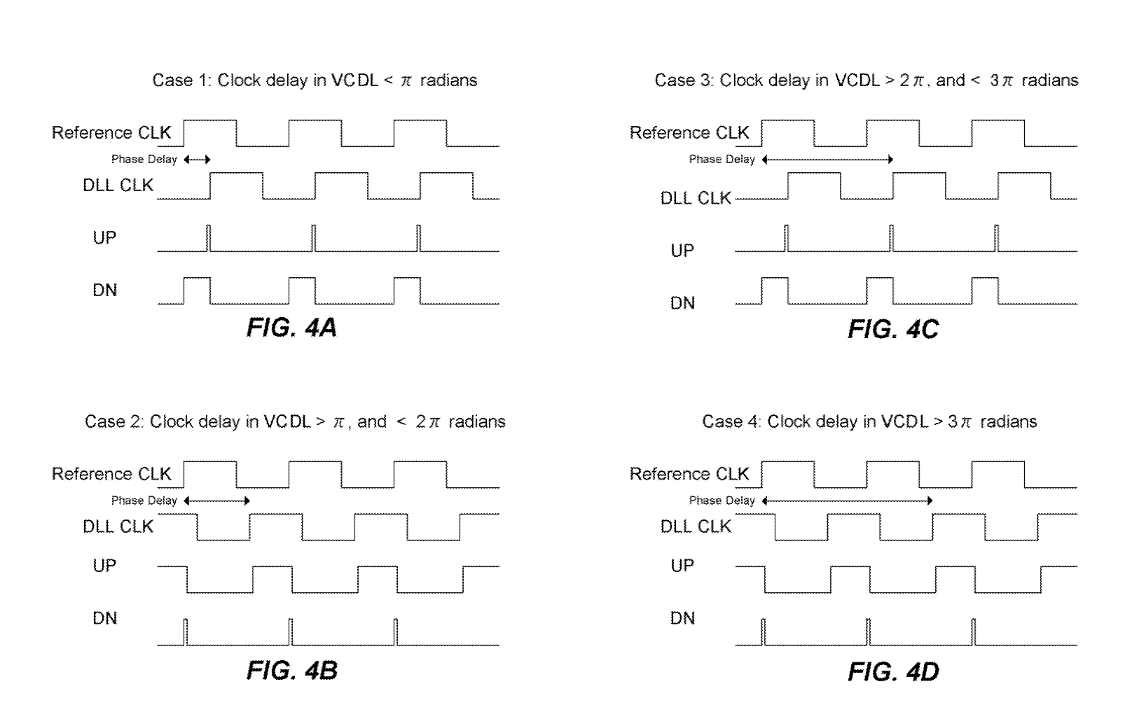

The above described problems are illustrated in FIGS. 4A-4D, for a VCDL 110 with total phase delay>2π radians and offset<π radians. FIG. 4A (case 1) shows the phase delay<π radians. In this case, the PD 104 generates longer DN pulses than UP pulses, although longer UP pulses are desired to increase the delay. FIG. 4B (case 2) shows the phase delay>π radians, and less than 2π radians (i.e., between π and 2π radians). Here the UP and DN signals are generated by the PD 104 correctly, and the DLL phase is increased to lock the output clock at 2π radians. FIG. 4C (case 3) shows the phase delay>2π radians, and less than 3π radians (i.e., between 2π and 3π radians). Here, the UP and DN signals are generated by the PD 104 correctly, and the DLL phase is decreased to lock the output clock back to 2π radians. Note that the UP and DN signals in FIGS. 4A and 4C are identical, which is illustrative of the PD 104 not distinguishing between a phase delay<π radians and a phase delay between 2π and 3πradians. FIG. 4D (case 4) shows the phase delay>3π radians. In this case, the PD 104 generates longer UP pulses than DN pulses, although longer DN pulses are desired to decrease the delay. Note that the UP and DN signals in FIGS. 4B and 4D are identical, which is illustrative of the PD 104 not distinguishing between a phase delay between π and 2π radians and a phase delay>3π radians. The very short pulses in FIGS. 4A-4D are used to avoid the dead zone in the transfer function, as mentioned above.

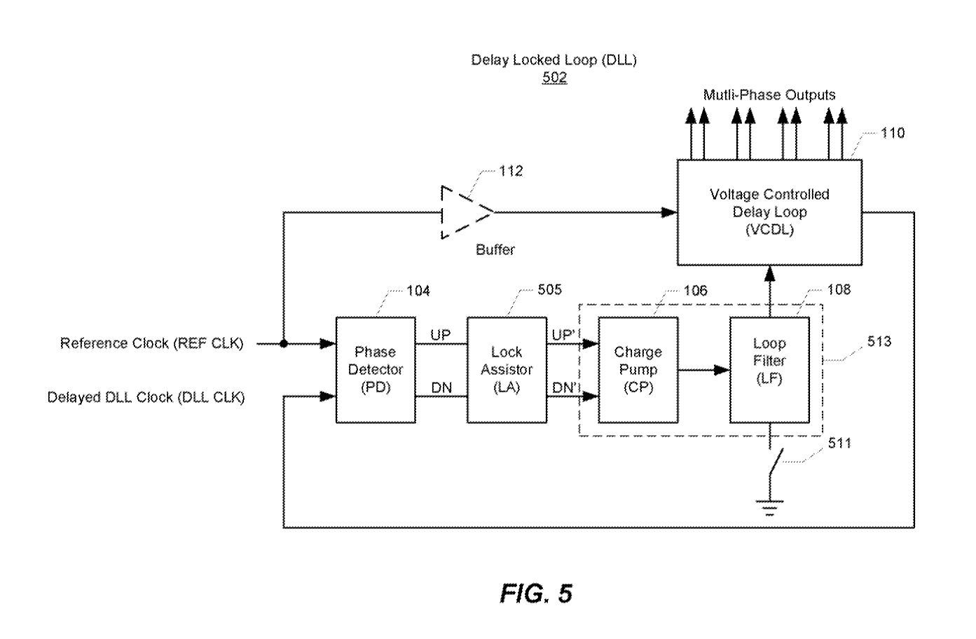

Reference is now made to FIG. 5, which is used to describe a DLL 502 according to an embodiment of the present invention. Elements in FIG. 5 that are the same or similar to corresponding elements in FIG. 1 are labeled with like numerals or reference designators, and need not be described again. A comparison between FIG. 1 and FIG. 5 reveals that in FIG. 5 a new block called a lock assistor (LA) 505 (which can also be referred to as a lock assist circuit) is included between the PD 102 and the CP 106 in the DLL 502. Essentially, the LA 505 selectively swaps the UP and DN outputs of the PD 102. The outputs of the LA 505 are labeled UP′ and DN′ (which can be expressed as “up prime” and “down prime”, respectively), and can also be referred to as lock assistor output signals, or as lock assisted phase detection signals. Additionally, there is a reset switch 511, which sets the voltage of the LF 108 to zero when starting up the DLL 502. The CP 106 and the LF 108 can be collectively referred to as a control voltage generator 513, since they collectively produce a control voltage signal (for controlling the VCDL 110) in response to the UP′ and DN′ signals. More specifically, the control voltage signal output by the control voltage generator 513 (which is input to the VCDL 110) increases when the UP′ pulses are longer than the DN′ pulses, which causes the delay through the VCDL 110 to increase. Conversely, the control voltage signal output by the control voltage generator 513 decreases when the DN′ pulses are longer than the UP′ pulses, which causes the delay through the VCDL 110 to decrease.

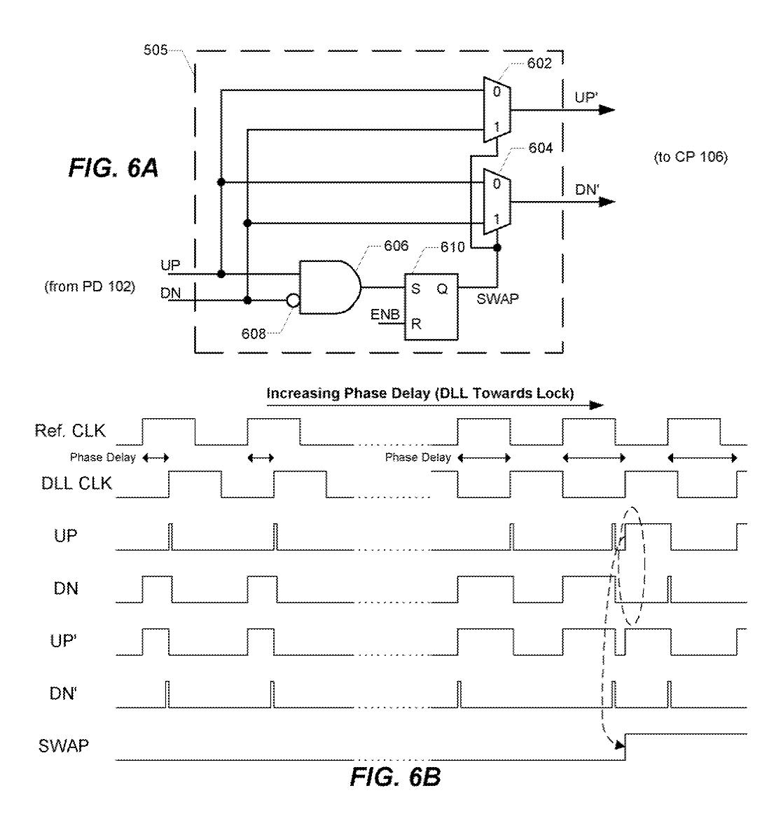

An implementation of the LA 505, according to an embodiment of the present invention, is shown FIG. 6A, and a corresponding exemplary timing diagram is shown in FIG. 6B. This implementation uses simple logic gates in order to overcome the potential problem of the DLL never locking, as well as to prevent harmonic locking as a side-effect of the lock assistance function. Referring to FIG. 6A, the LA 505 includes two multiplexers (MUXes) 602 and 604, an AND gate 606 with an inverted input 608, and a set/reset (SR) flip-flop 610 (which itself, can be made from simple logic gates, e.g., two NOR gates). The LA 505 operates as follows. When the reset switch 511 (in FIG. 5) is used to set the control voltage signal output of the LF 108 to zero, the delay through the VCDL 110 of the reference clock is guaranteed to be at a minimum. The multiplexers (MUXes) 602 and 604 essentially control the connections of the UP and DN signals to the CP 106.

Referring briefly back to FIG. 1, while the phase delay through the VCDL 110 is less than π radians, the PD 104 design is such that the DN signal from the PD is high, whereas the UP signal is low. If the UP and DN signals output by the PD are directly provided to the CP 106, then the voltage of the LF 108 would never increase, and the DLL could never lock. This is because of the symmetry of the operation of the PD 104 as described above, and shown in FIG. 4A. In other words, with a phase delay less than π radians, the PD 104 outputs DN pulses which try to decrease the delay through the VCDL 110. But since the delay is already at a minimum, the control voltage signal output by the LF 108 never increases and the DLL will never lock.

Referring again to FIGS. 5, 6A and 6B, in accordance with an embodiment of the present invention, while the phase delay through the VCDL 110 is less than π radians, the MUXes 602 and 604 of the LA 505 swap the UP and DN signals output by the PD 104, before such outputs are provided to the CP 106. Thus, the DN signal which is high (and would conventionally cause the CP to sink current) becomes the UP′ signal to the CP 106 (and instead, causes the CP to source current), and the UP signal which is low becomes the DN′ signal to the CP 106. In this way, the CP 106 is controlled to source current, thus increasing the control voltage signal output by the LF 108 and bringing the DLL 502 towards a locked state as the phase delay through the VCDL 110 is increased.

At some point, the LA 505 will need to change control of the UP and DN signals so that the UP signal becomes the UP′ signal, and the DN signal becomes the DN′ signal. In other words, the LA 505 needs to know when to stop swapping the UP and DN signals. The point at which this is done is when the phase delay through the VCDL 110, as controlled by voltage of the LF 108, is greater than π radians. To detect when this occurs, the select signal for the MUXes 602 and 604 is controlled by the output of the SR flip-flop 610, which is the signal labeled “swap” in FIGS. 6A and 6B. When the UP signal becomes high and the DN signal is low, the phase delay through the VCDL 110 has increased beyond π radians. The output of the AND gate 606 (which receives the UP signal and the inverted version of the DN signal), as shown in FIG. 6A, sets the SR flip-flip 610 to change the select signal (called “swap”) for the MUXes 602 and 604. Now, the UP signal is the UP′ signal for the CP 106 and the DN signal is the DN′ signal for the CP 106. In other words, from this point in time forward the LA 505 no longer swaps the outputs of the PD 104 before such outputs are provided to the CP 106. In accordance with an embodiment, the SR flip-flip 610 is not reset until the DLL 502 is powered down again and thereafter re-started.

As mentioned above, FIG. 6B includes timing waveforms corresponding to operation of the LA 505. Noted in FIG. 6B is the time where the UP signal becomes high before the DN signal, which causes the “swap” signal to become high and the outputs of the MUXes 602 and 604 (which are the UP′ and DN′ outputs of the LA 505) to change. In the embodiment described with reference to FIGS. 6A and 6B, the LA 505 swaps the UP and DN outputs of the PD when the swap signal is low, and does not swap (which can also be referred to as “un-swaps”) the outputs of the PD when the swap signal is high.

One of ordinary skill in the art will appreciate that the circuitry of the LA can be modified such that the UP and DN outputs of the PD are swapped when the “swap” signal is high, and are not swapped when the “swap” signal is low. Additionally, one of ordinary skill in the art would also appreciate that a myriad of alternative logic circuitry configurations can be used to control whether or not to swap the UP and DN outputs of the PD (or produce the UP′ and DN′ outputs), by detecting when the phase delay through the VCDL 110, as controlled by voltage of the LF 108, is greater than π radians. Such alternative configurations are also within the scope of the present invention.

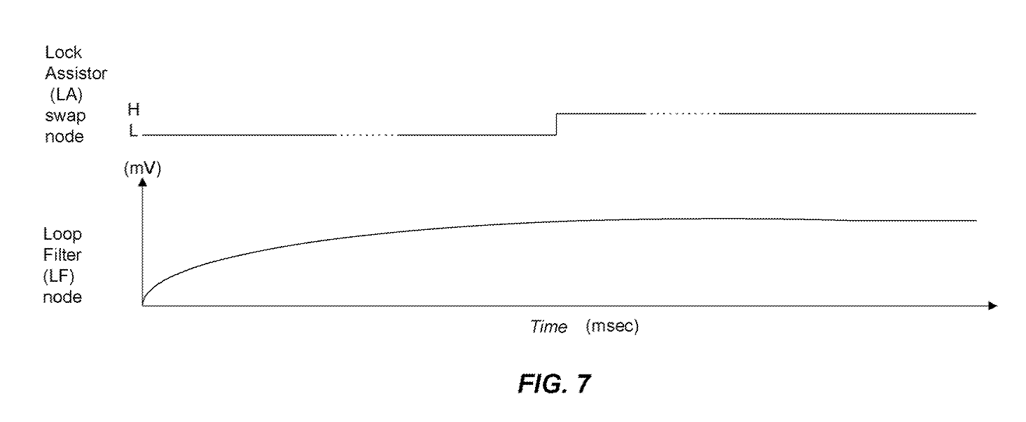

FIG. 7 shows the relationship of the control voltage signal output by the LF 108 of the DLL 502 to the “swap” signal. As the DLL approaches lock, the control voltage signal output by the LF 108 increases. As this voltage increases, the delay through the VCDL 110 increases so that the phase becomes greater than π radians. When this occurs, the “swap” signal changes polarity so that the UP and DN signal are no longer swapped, and the DLL feedback loop will cause the phase to keep increasing until the DLL locks.

In accordance with specific embodiments, to ensure locking, there are a few rules that should be followed. When implementing the LA 505 using the configuration shown in FIG. 6A, the SR flip-flop 610 should only be reset when the DLL 502 is powered down. Otherwise, the “swap” control signal for the MUXs 602 and 604 may change, and the usage of the UP and DN signals by the CP 106 will not be used properly and the DLL 502 using the LA 505 may fail to lock. Also, the PD 104 and the CP 106 should not have a dead zone (the concept being described above in FIG. 2B). If there is a dead zone, then it is possible that the condition for setting the “swap” signal to change the usage of the UP and DN signals from the PD 104 will not occur, and again the DLL 502 will not lock. Finally, the inputs to the AND gate 606 in the LA 505 may require hysteresis, e.g., using a Schmitt trigger circuit, for noise immunity to ensure that the condition to toggle the “swap” signal high (logical ‘1’) occurs in the presence of noise.

The lock assistor 505 ensures that the voltage on the LF 108 increases towards a value at which the DLL will attain lock. Under this condition, the control voltage to the VCDL 110 is such that the phase delay through the VCDL 110 is 2π radians. Then, the input reference clock REF CLK is delayed by 2π radians to become the output DLL CLK. Because this is the case (the lock assistor 505 ensured that the VCDL control voltage increased so that the DLL became locked), and because the VCDL 110 control voltage started at a minimum, the phase delay through the VCDL 110 will not be able to increase beyond 2π radians, ensuring that harmonic locking does not occur.

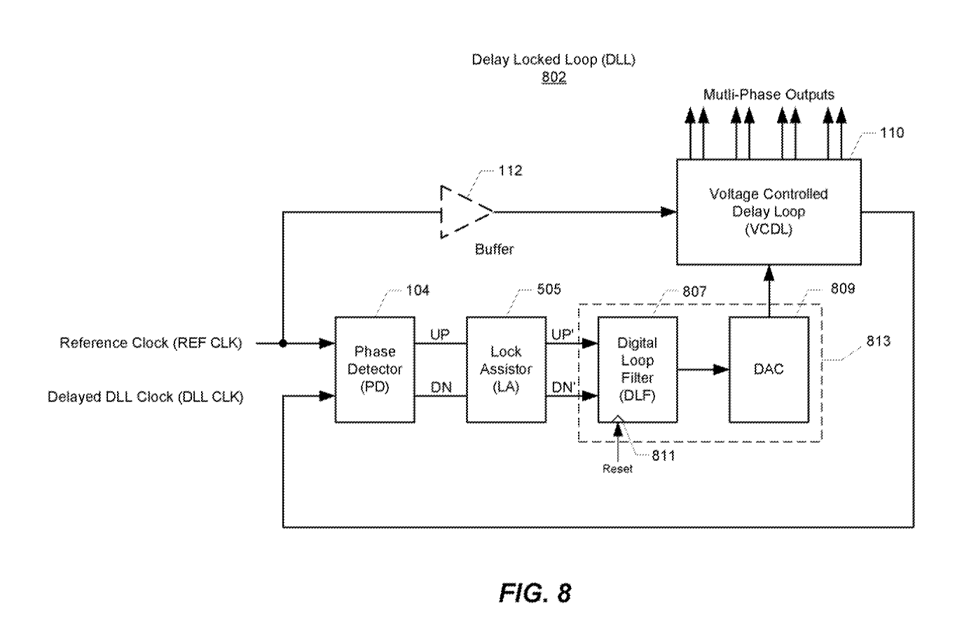

The lock assistor 505, discussed above, was shown as being used in the analog DLL 502 that includes the CP 106 and the LF 108. As shown in FIG. 8, in accordance with alternative embodiments of the present invention, the LA 505 can be used in a digital DLL 802 that includes digital loop filter (DLF) 807 and a digital-to-analog converter (DAC) 809 in place of the CP 106 and LF 108. The DLF 807 produces a digital value in dependence on the UP′ and DN′ signals produced by the LA 505. The digital value produced by the DLF 807 is converted to an analog control voltage signal, by the DAC 809, and the control voltage signal is used to control the VCDL 110 in the same manner that the control voltage signal produced by the LF 108 controls the VDCL 110 in FIG. 5. More specifically, when the UP′ signal is high, the value produced by the DLF 807 is increased, and when the DN′ is high, the value produced by the DLF 807 is decreased. The DLF 807 can be implemented, e.g., using an up-down counter, a finite impulse response (FIR) filter, or an infinite impulse response (IIR) filter, but is not limited thereto. Additionally, there is a reset input 811, which sets the digital value stored in the DLF 807 to zero when starting up the DLL 802. The DLF 807 and the DAC 809 can be collectively referred to as a control voltage generator 813, since they collectively produce a control voltage signal for controlling the VCDL 110 in response to the UP′ and DN′ signals. More specifically, the control voltage signal output by the control voltage generator 813 (which is input to the VCDL 110) increases when the UP′ pulses are longer than the DN′ pulses, which causes the delay through the VCDL 110 to increase. Conversely, the control voltage signal output by the control voltage generator 813 decreases when the DN′ pulses are longer than the UP′ pulses, which causes the delay through the VCDL 110 to decrease. Alternatively, the VCDL may be digitally controlled directly by the DLF 807, eliminating the need for the DAC 809, in which case the voltage generator 813 would only include the DLF 807. In this case, the VCDL would be controlled by digital values as opposed to an analog voltage.

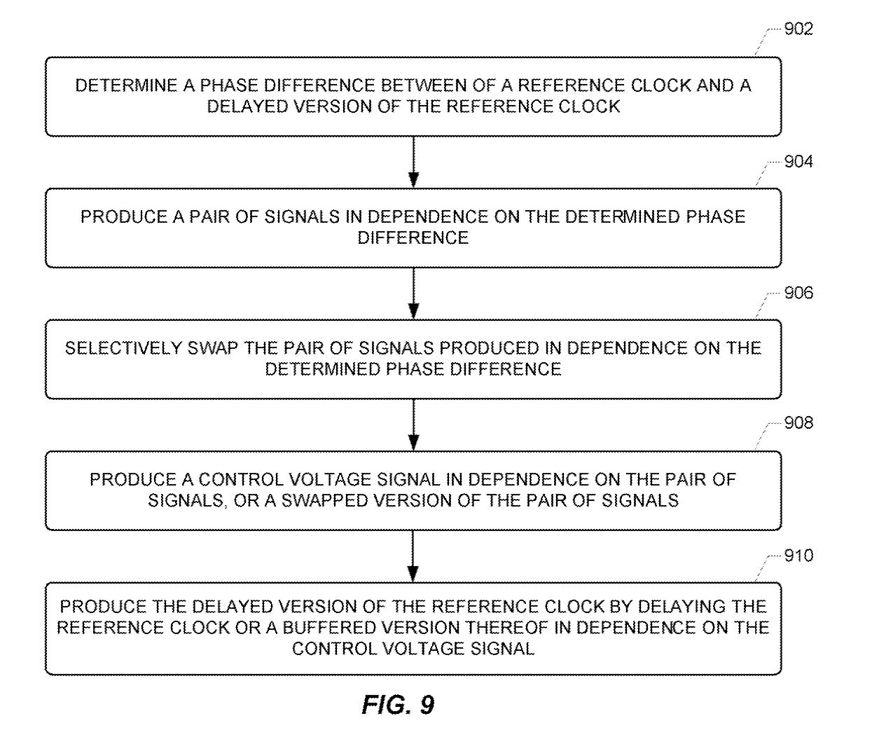

FIG. 9 is a high level flow diagram that is used to summarize methods according to various embodiments of the present invention. Referring to FIG. 9, at step 902, a phase difference between a reference clock and a delayed version of the reference clock is determined. At step 904, a pair of signals (e.g., the UP and DN signals) is produced in dependence on the determined phase difference. At step 906, the signals (e.g., the UP and DN signals) produced at step 904 are selectively swapped in dependence on the determined phase difference. In accordance with an embodiment, as was described above, the pair of signals are swapped when the phase difference, between the reference clock and the delayed version of the reference clock, is less than π radians; and the pair of signals are not swapped when the phase difference, between the reference clock and the delayed version of the reference clock, is greater than π radians. At step 908, a control voltage signal is produced in dependence on the pair of signals, or a swapped version of the pair of signals, which result from step 906. At step 910, the delayed version of the reference clock is produced by delaying the reference clock, or a buffered version thereof, in dependence on the control voltage signal. Additional details of methods according to embodiments of the present invention can be appreciated from the above discussion of FIGS. 1-8.

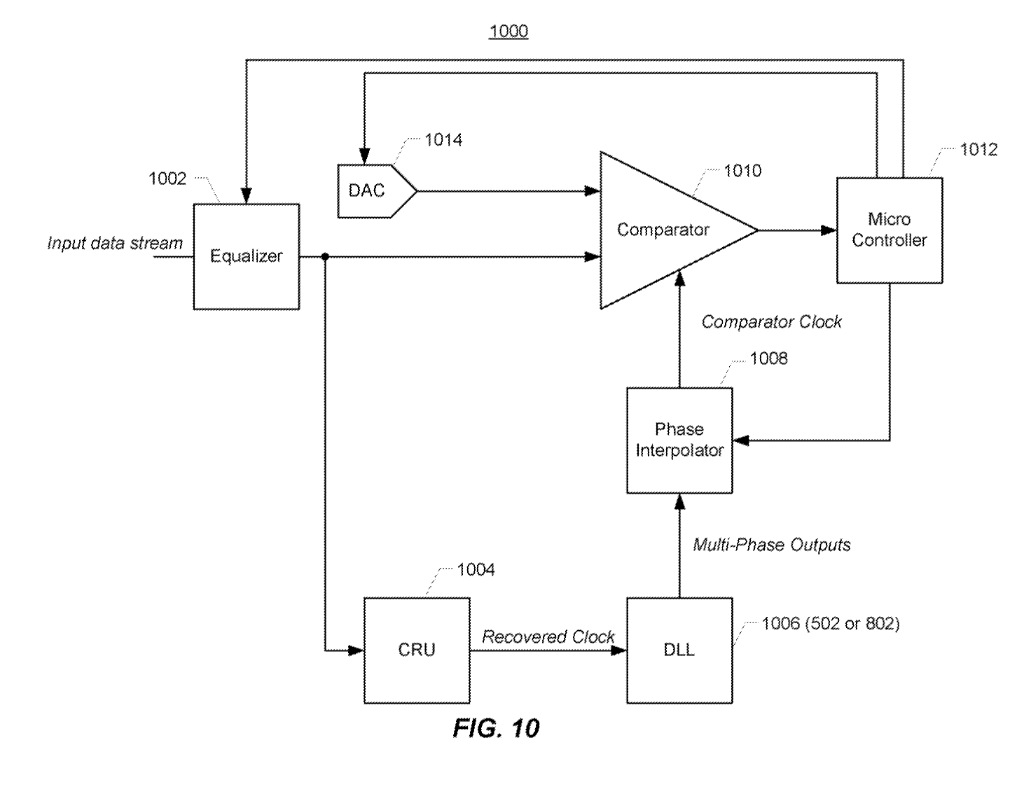

FIG. 10 illustrates an eye monitor circuit 1000 including a DLL 1006, according to an embodiment of the present invention. The DLL 1006 can be implemented as either the DLL 502 discussed with reference to FIG. 5, or the DLL 802 discussed with reference to FIG. 8. A serial binary input data stream that includes an embedded clock signal is provided to an equalizer 1002 that outputs an equalized version of the serial data stream, which is provided to a clock recovery unit (CRU) 1004 and a comparator 1010. The CRU 1004 extracts the embedded clock signal and forwards the extracted clock signal to the DLL 1006. This recovered clock signal functions as the reference clock (REF CLK) discussed above. The DLL 1006 produces multi-phase outputs in dependence on the recovered clock signal. More specifically, the VCDL 110 of the DLL 502 or 802 (one of which is used to implement DLL 1006) produces the multi-phase outputs, in accordance with the embodiments of the present invention described above, in a manner that avoids the problem of the DLL possibly never locking, and in a manner the avoids harmonic locking. The multi-phase outputs of the DLL 1006 are provided to a phase interpolator 1008, which generates a single phase clock signal that is provide to the comparator 1010. A microcontroller 1012 controls the phase interpolator 1008 and a digital-to-analog converter (DAC) 1014, wherein the DAC 1014 is used to produce a reference voltage provided to the comparator 1010. Based on the single phase clock signal produced by the phase interpolator 1008, the comparator 1010 samples the equalized version of the serial data stream at different points in time within an eye of data stream, in order to construct an eye diagram (e.g., on an oscilloscope) that can be used to control a gain provide by the equalizer 1002, to improve bit error rate (BER), a common metric in serial data transmission to monitor signal integrity. The DLLs 502 and 802 described above can alternatively be used in other systems, e.g., for clock synchronization, to control data sampling and/or to controlling flip-flops within a central processing unit (CPU). These are just a few exemplary uses of the DLLs of embodiments of the present invention, which are not meant to be all encompassing.

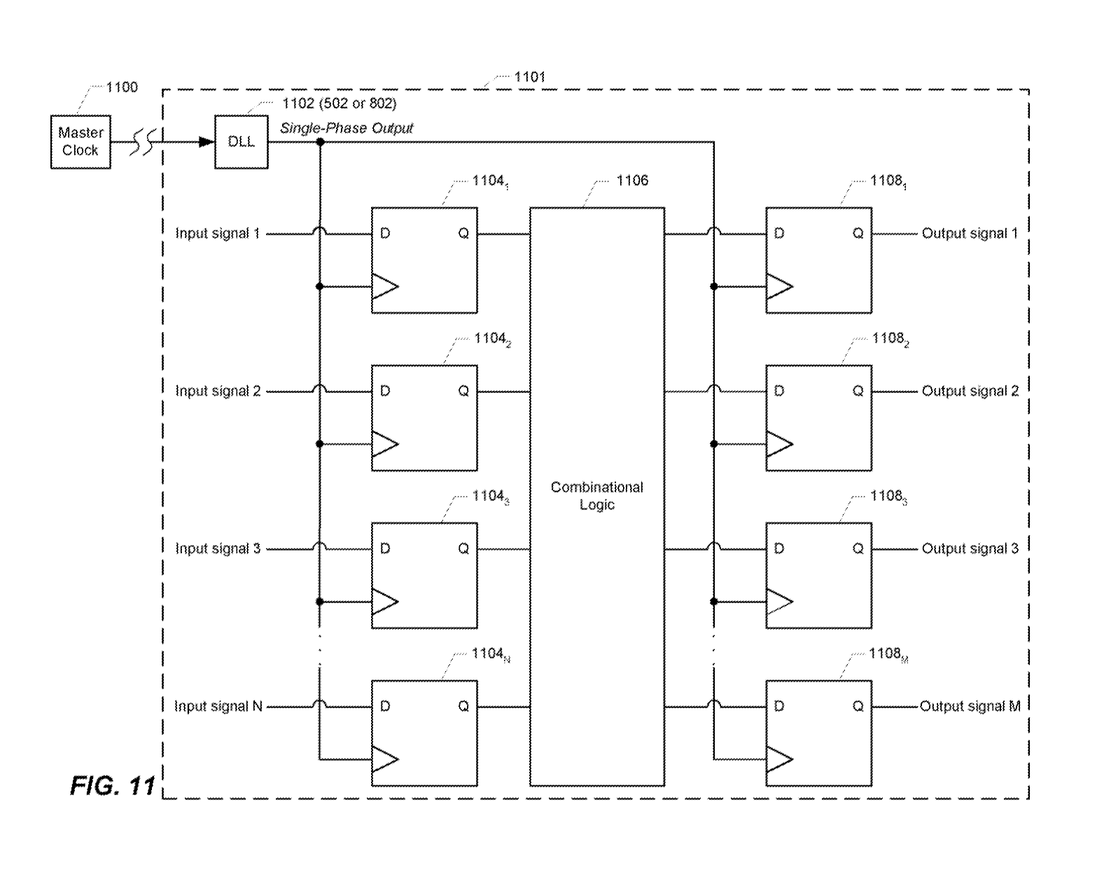

FIG. 11 is used to illustrate how a DLL of an embodiment of the present invention can be used to synchronize signals within a subsystem 1001 that is part of a larger system (e.g., a microcontroller) to a clock (e.g., a master clock) of the larger system. As shown in FIG. 11, a DLL 1102 (which can be implemented as the DLL 502 or 802 described above) receives a clock signal from a master clock 1100. This clock signal functions as the reference clock (REF CLK) for the DLL 1102. The master clock 1100 may be a sufficient distance from the subsystem 1101 such that it is skewed (i.e., out of phase) due to RC delays in the wire(s) and/or trace(s) between the master clock 1000 and the subsystem 1001. The various input signals shown in FIG. 11 represent digital signals produced by components within the subsystem 1001 or received by the subsystem 1001 from one or more external subsystems. The various output signals shown in FIG. 11 represent digital signals that are provided to other components with the subsystem 1001 or to one or more external subsystems. Each input signal is provided to a corresponding D flip-flop 1104, which also receives a single-phase output signal from the DLL 1102 at the clock input of the D flip-flop. In this manner, the D flip-flops 1104₁-1104_{N} function as a shift register that synchronizes, to the output signal from the DLL 1102, all the of the input signals being provided to combinatorial logic 1106. The combinatorial logic 1106 can include any type of know logic (e.g., AND, NAND, OR, NOR, XOR, etc.) combined in any possible manner. Outputs of the combinatorial logic 1106 are provided to further D flip-flops 1108₁-1108ₘ, which also receive the single-phase output signal from the DLL 1102 at the clock inputs of the D flip-flops. Here, the D flip-flops 1108₁-1108ₘ function as a shift register that synchronizes all of the output signals.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that this invention be limited only by the claims and the equivalents thereof.

1. A delay locked loop (DLL), comprising:
a phase detector (PD) configured to
determine a phase difference between a reference clock and a delayed version of the reference clock, and
produce a pair of phase detector output signals in dependence on the determined phase difference;
a lock assistor (LA) configured to
receive the pair of phase detector output signals, and
produce a pair of lock assistor output signals by selectively swapping the phase detector output signals;
a control voltage generator configured to receive the pair of lock assistor output signals and produce a control voltage signal in dependence on the pair of lock assistor output signals; and
a voltage controlled delay line (VCDL) configured to
receive the control voltage signal produced by the control voltage generator,
receive the reference clock or a buffered version thereof, and
output the delayed version of the reference clock,
wherein a delay through the VCDL is dependent on the received control voltage signal produced by the control voltage generator.

2. The DLL of claim 1, wherein the LA is configured to:
swap the phase detector output signals when the phase difference, between the reference clock and the delayed version of the reference clock, is less than π radians; and
not swap the phase detector output signals when the phase difference, between the reference clock and the delayed version of the reference clock, is greater than πradians.

3. The DLL of claim 1, wherein:
the pair of phase detector output signals, which are received by the lock assistor, comprise an UP signal and a DN signal;
the lock assistor output signals comprise an UP′ signal and a DN′ signal; and
the LA is configured to produce the UP′ and DN′ signals by selectively swapping the UP and DN signals.

4. The DLL of claim 4, wherein the LA comprises:
a first multiplexer that receives the UP and DN signals, and outputs one of the UP and DN signals as the UP′ signal; and
a second multiplexer that receives the UP and DN signals, and outputs the other one of the UP and DN signals as the DN′ signal.

5. The DLL of claim 4, wherein the LA further comprises:
logic circuitry configured to receive the UP and DN signals and control the first and second multiplexers based in the UP and DN signals.

6. The DLL of claim 1, further comprising:
a switch configured to selectively set the voltage signal produced by the LF to zero.

7. The DLL of claim 6, wherein the switch is configured to set the voltage signal produced by the LF to zero when the DLL is powered-up.

8. The DLL of claim 1, wherein the control voltage generator comprises:
a charge pump (CP) configured to selectively source or sink current in dependence on the pair of lock assistor output signals;
a loop filter (LF) configured to filter an output of the charge pump to thereby produce the control voltage signal.

9. The DLL of claim 1, wherein the control voltage generator comprises:
a digital loop filter (DLF) configured to increase or decrease a digital value in dependence on the pair of lock assistor output signals; and
a digital-to-analog converter (DAC) configured to convert the digital value of the DLF to the control voltage signal.

10. A lock assistor for use with a delay locked loop (DLL), wherein the DLL includes
a phase detector (PD) configured to
determine a phase difference between of a reference clock and a delayed version of the reference clock, and
produce a pair of phase detector output signals in dependence on the determined phase difference;
a control voltage generator configured to produce a control voltage signal in dependence on the pair of lock assistor output signals; and
a voltage controlled delay line (VCDL) configured to
receive the control voltage signal,
receive the reference clock or a buffered version thereof, and
output the delayed version of the reference clock,
wherein a delay through the VCDL is dependent on the control voltage signal produced by the control voltage generator;
wherein the lock assistor comprises:
circuitry configured to selectively swap the pair of phase detector output signals before said pair of phase detector output signals are provided to the control voltage generator.

11. The lock assistor of claim 10, wherein the circuitry of the lock assistor is configured to:
swap the phase detector output signals when the phase difference, between the reference clock and the delayed version of the reference clock, is less than π radians; and
not swap the phase detector output signals when the phase difference, between the reference clock and the delayed version of the reference clock, is greater than πradians.

12. The lock assistor of claim 10, wherein:
the pair of phase detector output signals, which are received by the lock assistor, comprise an UP signal and a DN signal;
the lock assistor output signals comprise an UP′ signal and a DN′ signal; and
the circuitry of the lock assistor is configured to produce the UP′ and DN′ signals by selectively swapping the UP and DN signals.

13. The lock assistor of claim 12, wherein the circuitry of the lock assistor comprises:
a first multiplexer that receives the UP and DN signals, and outputs one of the UP and DN signals as the UP′ signal; and
a second multiplexer that receives the UP and DN signals, and outputs the other one of the UP and DN signals as the DN′ signal.

14. The lock assistor of claim 13, wherein the circuitry of the lock assistor further comprises:
logic circuitry configured to receive the UP and DN signals and control the first and second multiplexers based in the UP and DN signals.

15. A method, comprising:
(a) determining a phase difference between of a reference clock and a delayed version of the reference clock;
(b) producing a pair of phase detection signals in dependence on the determined phase difference;
(c) selectively swapping the pair of phase detection signals produced in dependence on the determined phase difference to thereby produce a pair of lock assisted phase detection signals;
(d) producing a control voltage signal in dependence on the pair of lock assisted phase detection signals produced at step (c);
(e) producing the delayed version of the reference clock by delaying the reference clock or a buffered version thereof in dependence on the control voltage signal.

16. The method of claim 15, wherein step (c) comprises:
(c.1) swapping the pair of phase detection signals when the phase difference, between the reference clock and the delayed version of the reference clock, is less than πradians; and
(c.2) not swapping the pair of phase detection signals when the phase difference, between the reference clock and the delayed version of the reference clock, is greater than π radians.

17. The method of claim 15, further comprising setting the control voltage signal to zero when circuitry used to produce the reference clock and the delayed version of the reference clock is powered-up.

18. The method of claim 15, wherein step (d) includes:
(d.1) selectively sourcing current to a node or sinking current from the node in dependence on the pair of lock assisted phase detection signals; and
(d.2) filtering the voltage at the node to thereby produce the control voltage signal.

19. The method of claim 15, wherein step (d) includes:
(d.1) increasing or decreasing a digital value in dependence on the pair of lock assisted phase detection signals produced at step (c); and
(d.2) converting the digital value to the control voltage signal.

20. A system, comprising:
an equalizer that receives a serial data stream and outputs an equalized version of the serial data stream;
a clock recovery unit (CRU) that extracts a reference clock signal from the equalized version of the serial data stream;
delay locked loop (DLL) that receives the reference clock from the CRU and produces multi-phase outputs;
a phase interpolator that receives the multi-phase outputs produced by the DLL and produces a single phase clock signal;
a comparator that compares the equalized version of the serial data stream to a reference voltage in dependence on the single phase clock signal produced by the phase interpolator; and
a microcontroller that receives outputs of the comparator and adjusts a gain of the equalizer in dependence thereon;
wherein the DLL comprises
a phase detector (PD) configured to
determine a phase difference between of the reference clock produced by the CRU and a delayed version of the reference clock, and
produce a pair of phase detector output signals in dependence on the determined phase difference;
a lock assistor (LA) configured to
receive the pair of phase detector output signals, and
produce a pair of lock assistor output signals by selectively swapping the phase detector output signals;
a control voltage generator configured to receive the pair of lock assistor output signals and produce a control voltage signal in dependence on the pair of lock assistor output signals; and
a voltage controlled delay line (VCDL) configured to
receive the control voltage signal produced by the control voltage generator,
receive the reference clock or a buffered version thereof,
output the delayed version of the reference clock, and
output the multi-phase outputs of the DLL that are provided to the phase interpolator.

21. A subsystem, comprising:
delay locked loop (DLL) that receives a clock signal and outputs single-phase output signal;
a first plurality of D-flip flops each including a data input, a clock input and an output;
a second plurality of D-flip flops each including a data input, a clock input and an output;
combinatorial logic connected between the outputs of the first plurality of D-flip flops and the inputs of the second plurality of D-flip flops;
wherein the single phase output signal that is output by the DLL is provided to the clock inputs of the first and second plurality of D-flip flops to thereby synchronize inputs signals to, and output signal from, the combinatorial logic;
wherein the DLL comprises
a phase detector (PD) configured to
determine a phase difference between of the received clock signal and a delayed version of the received clock signal, and
produce a pair of phase detector output signals in dependence on the determined phase difference;
a lock assistor (LA) configured to
receive the pair of phase detector output signals, and
produce a pair of lock assistor output signals by selectively swapping the phase detector output signals;
a control voltage generator configured to receive the pair of lock assistor output signals and produce a control voltage signal in dependence on the pair of lock assistor output signals; and
a voltage controlled delay line (VCDL) configured to
receive the control voltage signal produced by the control voltage generator,
receive the clock signal or a buffered version thereof,
output the delayed version of the clock signal, and
output the single-phase output signal that is provided to the clock inputs of the first and second plurality of D-flip flops.
